(19) United States
(12) Patent Application Publication
(10) Pub. No.: US 2024/0254366 A1
(43) Pub. Date: Aug. 1, 2024

(54) POLISHING COMPOSITION, POLISHING METHOD, AND METHOD OF MANUFACTURING SEMICONDUCTOR SUBSTRATE

(71) Applicant: FUJIMI INCORPORATED, Aichi (JP)

(72) Inventors: Haruka ASANO, Aichi (JP); Daiki ITO, Aichi (JP)

(21) Appl. No.: 18/421,013

(22) Filed: Jan. 24, 2024

(30) Foreign Application Priority Data
Jan. 27, 2023 (JP) 2023-010766
Nov. 27, 2023 (JP) 2023-199620

(51) Int. Cl. C09G 1/18; B24B 37/04; C09G 1/02; C09G 1/16; H01L 21/306; H01L 21/3105

(52) U.S. Cl. CPC C09G 1/18; B24B 37/044; C09G 1/02; C09G 1/16; H01L 21/30625; H01L 21/31053

(57) ABSTRACT

The present invention provides a method capable of increasing a ratio (selection ratio) of a polishing removal rate of silicon oxide or silicon nitride to a polishing removal rate of polysilicon and further reducing residues (preferably organic residues) on a surface of a polished object to be polished. The present invention is a polishing composition containing colloidal silica, an inorganic salt containing no halogen, and a water-soluble polymer, in which a product of a valence number (unit: valency) of an anion of the inorganic salt and a concentration (unit: mM) of the anion in the polishing composition is 57 or more.

### TECHNICAL FIELD

The present invention relates to a polishing composition, a polishing method, and a method of manufacturing a semiconductor substrate.

### BACKGROUND

In recent years, in accordance with high integration and high performance of large scale integration (LSI), a novel microfabrication technique has been developed. A chemical mechanical polishing (CMP) method is one of them, and it is a technique that is frequently used in flattening of an interlayer insulating film, formation of a metal plug, and formation of embedded wiring (damascene wiring) in an LSI manufacturing process, particularly, in a multilayer wiring forming process.

The CMP has been applied to each process in semiconductor manufacturing, and as one aspect thereof, for example, application to a gate forming process in transistor production can be exemplified. When a transistor is produced, a Si-containing material such as silicon, silicon oxide (SiO₂), polysilicon (polycrystalline silicon), or silicon nitride (Si₃N₄) may be polished. In addition, for example, a composite material such as an object to be polished containing polysilicon and silicon oxide or silicon nitride may be polished.

As a technique for polishing such a composite material, for example, WO 2017/163910 A (corresponding to the specification of US 2020/299,543 A) discloses a polishing composition containing silica particles on which an organic acid is immobilized, a wetting agent, and a polishing removal rate inhibitor for a material having a silicon-silicon bond, and having a pH of less than 7.

### SUMMARY

In a case where the object to be polished containing polysilicon and silicon oxide or silicon nitride is polished as described above, there is a demand for improving a ratio (selection ratio) of a polishing removal rate of silicon oxide or silicon nitride to a polishing removal rate of polysilicon. However, in the technique described in WO 2017/163910 A (corresponding to the specification of US 2020/299,543 A), the polishing removal rates of the respective materials are substantially equal, and there is room for improvement in order to improve the selection ratio. In addition, in the technique described in WO 2017/163910 A (corresponding to the specification of US 2020/299,543 A), a phenomenon that a reduction in residues on an object to be polished after polishing (polished object to be polished) is insufficient is also observed, and there is room for improvement in this respect.

Therefore, an object of the present invention is to provide a method capable of increasing a ratio (selection ratio) of a polishing removal rate of silicon oxide or silicon nitride to a polishing removal rate of polysilicon and further reducing residues (preferably organic residues) on a surface of a polished object to be polished.

The present inventors have conducted extensive studies in view of the above problems. As a result, the present inventors have found that the above problems are solved by a polishing composition containing colloidal silica, an inorganic salt containing no halogen, and a water-soluble polymer, in which a product of a valence number (unit: valency) of an anion of the inorganic salt and a concentration (unit: mM) of the anion in the polishing composition is 57 or more, thereby completing the present invention.

### DETAILED DESCRIPTION

According to an embodiment of the present invention, there is provided a polishing composition containing colloidal silica, an inorganic salt containing no halogen, and a water-soluble polymer, in which a product of a valence number (unit: valency) of an anion of the inorganic salt and a concentration (unit: mM) of the anion in the polishing composition is 57 or more. According to such a polishing composition of the present invention, a ratio (selection ratio) of a polishing removal rate of silicon oxide or silicon nitride to a polishing removal rate of polysilicon can be high, and residues (preferably organic residues) on a surface of a polished object to be polished can be further reduced.

Hereinafter, for convenience of description, the product of the valence number (unit: valency) of the anion of the inorganic salt and the concentration (unit: mM) of the anion in the polishing composition is also referred to as “parameter A”.

The reason why the above effect is obtained by the polishing composition of the present invention is not clear in detail, but is considered to be the following mechanism. Note that this mechanism is based on presumption, and the technical scope of the present invention is not limited by this mechanism.

The polishing composition of the present invention contains an inorganic salt containing no halogen, but it is considered that defects on the surface of the polished object to be polished are reduced particularly by the action of the anion contained in the inorganic salt. In a case where the anion is an oxoacid anion, it is considered that the oxoacid anion is adsorbed to pad debris which is an organic residue and the surface of the polished object to be polished, and the organic residues on the surface of the polished object to be polished are reduced by electrostatic repulsion. When the parameter A defined above is 57 or more, it is considered that both the pad debris and the surface of the polished object to be polished are easily adsorbed, a zeta potential is further reduced, the electrostatic repulsion is strengthened, and the residues (preferably organic residues) on the surface of the polished object to be polished are reduced.

In addition, when the anion is a thiocyanate ion, it is considered that the water-soluble polymer adsorbed to the surface of the polished object to be polished is swollen to further enhance hydrophilicity of the polished object to be polished. Therefore, it is considered that residues (preferably organic residues) that are hydrophobic are less likely to be attached to the polished object to be polished, and the residues (preferably organic residues) are reduced. When the parameter A is 57 or more, it is considered that the effect of enhancing the hydrophilicity of the polished object to be polished is further exhibited, and the residues (preferably, organic residues) on the polished object to be polished are reduced.

In addition, the polishing composition according to the present invention contains a water-soluble polymer. The water-soluble polymer is adsorbed to the surface of the object to be polished or the polished object to be polished, such that an effect of preventing reattachment of the residues (preferably organic residues) and inhibiting mechanical polishing action by colloidal silica is obtained. Due to such a mechanism of action, in the polishing composition of the present invention, particularly, the ratio (selection ratio) of the polishing removal rate of silicon oxide or silicon nitride to the polishing removal rate of polysilicon can be high, and the residues on the surface of the polished object to be polished can be further reduced.

In the present specification, the residue represents foreign matter attached to the surface of the polished object to be polished. Examples of the residues include, but are not particularly limited to, other residues such as organic residues, particle residues derived from abrasive grains contained in the polishing composition, residues composed of components other than the particle residues and the organic residues, a mixture of particle residues and the organic residues, and the like.

In the present specification, the organic residues represent components composed of an organic substance such as an organic low molecular weight compound, a polymer compound, or the like, an organic salt, or the like, among the foreign matter attached to the surface of the polished object to be polished. Examples of the organic residues attached to the polished object to be polished include pad debris generated from a pad used in a polishing process described below, components derived from additives contained in the polishing composition used in the polishing process, and the like.

Note that since the organic residues and other residues are greatly different in color and shape, whether or not the residues are organic residues can be visually determined by, for example, observation with a scanning electron microscope (SEM). In addition, whether or not the residues are organic residues may be determined by elemental analysis using an energy dispersive X-ray analyzer (EDX) attached to the SEM as necessary. The number of organic residues can be measured using a wafer defect inspection apparatus, or a wafer defect inspection apparatus and SEM or EDX elemental analysis. Specifically, the number of organic residues can be measured by the method described in Examples.

Hereinafter, embodiments of the present invention will be described in detail, but the present invention is not limited to the following embodiments, and can be variously modified within the scope of the claims. The embodiments described in the present specification can be other embodiments by being arbitrarily combined. In the present specification, unless otherwise specified, operation and measurement of physical properties and the like are performed under conditions of room temperature (20° C. or higher and 25° C. or lower)/relative humidity of 40% RH or more and 50% RH or less.

### [Colloidal Silica]

The polishing composition according to the present invention contains colloidal silica. The colloidal silica has an action of mechanically polishing an object to be polished, and improves a polishing removal rate of the object to be polished by the polishing composition.

As a method of producing colloidal silica, a sodium silicate method and a sol-gel method are exemplified, and colloidal silica produced by any production method is appropriately used as the colloidal silica according to the present invention. However, colloidal silica produced by the sol-gel method is preferable from the viewpoint of reducing metal impurities. Colloidal silica produced by the sol-gel method is preferable because it has a low content of corrosive ions such as metal impurities, chloride ions, or the like having a property of being diffused in a semiconductor. The production of colloidal silica by the sol-gel method can be performed using a conventionally known method, and specifically, colloidal silica can be obtained by using a hydrolysable silicon compound (for example, alkoxysilane or a derivative thereof) as a raw material and performing a hydrolysis and condensation reaction. In addition, commercially available colloidal silica may be used.

A shape of the colloidal silica is not particularly limited, and may be a spherical shape or a non-spherical shape. Specific examples of the non-spherical shape include, but are not particularly limited to, various shapes such as a polygonal prism shape such as a triangular prism, a tetragonal prism, or the like, a cylindrical shape, a straw bag shape in which a central portion of a cylinder is inflated compared to ends, a doughnut shape in which a central portion of a disk is perforated, a plate shape, a so-called cocoon shape having a constriction in a middle portion, a so-called associated type spherical shape in which a plurality of particles are integrated, a so-called konpeito shape having a plurality of protrusions on a surface, a rugby ball shape, and the like.

In the polishing composition of the present invention, the colloidal silica may have a cationic group on a surface thereof. That is, the colloidal silica may be cation-modified colloidal silica. Preferred examples of the cation-modified colloidal silica include colloidal silica having an amino group immobilized on a surface thereof. Examples of a method of producing colloidal silica having a cationic group include a method of immobilizing, on a surface of a silica particle, a silane coupling agent having an amino group such as aminoethyltrimethoxysilane, aminopropyltrimethoxysilane, aminoethyltriethoxysilane, aminopropyltriethoxysilane, aminopropyldimethylethoxysilane, aminopropylmethyldiethoxysilane, aminobutyltriethoxysilane, or the like, as described in JP 2005-162533 A. Therefore, colloidal silica having an amino group immobilized on a surface thereof (amino group-modified colloidal silica) can be obtained.

In addition, in the polishing composition of the present invention, the colloidal silica according to the present invention may have an anionic group on the surface thereof. That is, the colloidal silica may be anion-modified colloidal silica. Preferred examples of the anion-modified colloidal silica include colloidal silica having an anionic group such as a carboxylic acid group, a sulfonic acid group, a phosphonic acid group, an aluminate group, or the like immobilized on a surface thereof. A method of producing such colloidal silica having an anionic group is not particularly limited, and examples thereof include a method of reacting a silane coupling agent having an anionic group at a terminal thereof with colloidal silica.

As a specific example, when a sulfonic acid group is immobilized on colloidal silica, it is possible to use, for example, the method described in “Sulfonic acid-functionalized silica through quantitative oxidation of thiol groups”, Chem. Commun. 246-247 (2003). Specifically, it is possible to obtain colloidal silica having a sulfonic acid group immobilized on a surface thereof (sulfonic acid-immobilized colloidal silica or sulfonic acid-modified colloidal silica) by reacting a silane coupling agent having a thiol group such as 3-mercaptopropyltrimethoxysilane with colloidal silica and then oxidizing the thiol group with hydrogen peroxide.

When a carboxylic acid group is immobilized on colloidal silica, it is possible to use the method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, it is possible to obtain colloidal silica having a carboxylic acid group immobilized on a surface thereof (carboxylic acid-immobilized colloidal silica or carboxylic acid-modified colloidal silica) by coupling a silane coupling agent containing a photoreactive 2-nitrobenzyl ester to colloidal silica and then performing irradiation with light.

Among them, from the viewpoint that the ratio (selection ratio) of the polishing removal rate of silicon nitride to the polishing removal rate of polysilicon can be further increased and the residues on the polished surface of polysilicon can be further reduced, the colloidal silica is preferably anion-modified colloidal silica, and more preferably colloidal silica having a sulfonic acid group immobilized on a surface thereof (sulfonic acid-immobilized colloidal silica or sulfonic acid-modified colloidal silica).

A size of the colloidal silica according to the present invention is not particularly limited. For example, an average primary particle size of the colloidal silica is preferably 5 nm or more, more preferably 10 nm or more, still more preferably 15 nm or more, and particularly preferably 20 nm or more. As the average primary particle size of the colloidal silica increases, the polishing removal rate of the object to be polished by the polishing composition is improved. In addition, the average primary particle size of the colloidal silica is preferably 200 nm or less, more preferably 150 nm or less, still more preferably 100 nm or less, and particularly preferably 50 nm or less. As the average primary particle size of the colloidal silica decreases, it becomes easier to obtain a surface having fewer defects by polishing using the polishing composition. That is, the average primary particle size of the colloidal silica is preferably 5 nm or more and 200 nm or less, more preferably 10 nm or more and 150 nm or less, still more preferably 15 nm or more and 100 nm or less, and particularly preferably 20 nm or more and 50 nm or less. Note that the average primary particle size of the colloidal silica can be calculated, for example, on the assumption that the shape of the colloidal silica is a true sphere based on a specific surface area (SA) of the colloidal silica calculated from a BET method.

An average secondary particle size of the colloidal silica is preferably 10 nm or more, more preferably 15 nm or more, still more preferably 20 nm or more, and particularly preferably 25 nm or more. As the average secondary particle size of the colloidal silica increases, the resistance during polishing is reduced, and stable polishing becomes possible. In addition, the average secondary particle size of the colloidal silica is preferably 400 nm or less, more preferably 300 nm or less, still more preferably 200 nm or less, and particularly preferably 100 nm or less. As the average secondary particle size of the colloidal silica decreases, a surface area per unit mass of the colloidal silica increases, a contact frequency with the object to be polished is improved, and the polishing removal rate is further improved. That is, the average secondary particle size of the colloidal silica is preferably 10 nm or more and 400 nm or less, more preferably 15 nm or more and 300 nm or less, still more preferably 20 nm or more and 200 nm or less, and particularly preferably 25 nm or more and 100 nm or less. Note that the average secondary particle size of the colloidal silica can be measured by, for example, a dynamic light scattering method represented by a laser diffraction scattering method.

An average degree of association of the colloidal silica is preferably 5.0 or less, more preferably 4.0 or less, and still more preferably 3.0 or less. As the average degree of association of the colloidal silica decreases, defects can be further reduced. In addition, the average degree of association of the colloidal silica is preferably 1.0 or more, more preferably 1.5 or more, and still more preferably 2.0 or more. As the average degree of association of the colloidal silica increases, there is an advantageous effect of improving the polishing removal rate of the object to be polished by the polishing composition. That is, the average degree of association of the colloidal silica is preferably 1.0 or more and 5.0 or less, more preferably 1.5 or more and 4.0 or less, and still more preferably 2.0 or more and 3.0 or less. The average degree of association can be obtained by dividing the value of the average secondary particle size of the colloidal silica by the value of the average primary particle size.

An upper limit of an aspect ratio of the colloidal silica in the polishing composition is not particularly limited, and is preferably less than 2.0, more preferably 1.8 or less, and still more preferably 1.5 or less. Within this range, defects on the surface of the object to be polished can be further reduced. Note that the aspect ratio is an average of values obtained by taking the smallest rectangle circumscribing an image of colloidal silica particles by the scanning electron microscope and dividing a length of a long side of the rectangle by a length of a short side of the same rectangle, and can be obtained using general image analysis software. A lower limit of the aspect ratio of the colloidal silica in the polishing composition is not particularly limited, and is preferably 1.0 or more.

The size (average primary particle size, average secondary particle size, average degree of association, or the like) of the colloidal silica can be appropriately controlled by a selection of the method of producing colloidal silica and the like.

A concentration (content) of the colloidal silica in the polishing composition is not particularly limited. In a case of a polishing composition used for polishing an object to be polished as a polishing solution as it is (it is typically a slurry-like polishing solution, and may be referred to as a working slurry or a polishing slurry), a lower limit of the concentration (content) of the colloidal silica in the polishing composition is preferably 0.1% by mass or more, more preferably 0.5% by mass or more, still more preferably 0.6% by mass or more, still more preferably 0.8% by mass or more, and particularly preferably 1% by mass or more, with respect to the total mass of the polishing composition. In addition, an upper limit of the concentration (content) of the colloidal silica in the polishing composition is preferably 15% by mass or less, more preferably 10% by mass or less, still more preferably 8% by mass or less, still more preferably 6% by mass or less, and particularly preferably 5% by mass or less, with respect to the total mass of the polishing composition.

That is, the concentration (content) of the colloidal silica is preferably 0.1% by mass or more and 15% by mass or less, more preferably 0.5% by mass or more and 10% by mass or less, still more preferably 0.6% by mass or more and 8% by mass or less, still more preferably 0.8% by mass or more and 6% by mass or less, and particularly preferably 1% by mass or more and 5% by mass or less, with respect to the total mass of the polishing composition.

In addition, in a case of a polishing composition (that is, a concentrated solution or an undiluted solution of a working slurry) that is diluted and used for polishing, from the viewpoint of storage stability, filterability, and the like, usually, the concentration (content) of the colloidal silica is preferably 30% by mass or less and more preferably 25% by mass or less with respect to the total mass of the polishing composition. In addition, from the viewpoint of taking advantages of the concentrated solution, in the case of the polishing composition (that is, the concentrated solution or the undiluted solution of the working slurry) that is diluted and used for polishing, the concentration (content) of the colloidal silica is preferably more than 1% by mass and more preferably 2% by mass or more with respect to the total mass of the polishing composition.

Note that, in a case where the polishing composition contains two or more kinds of colloidal silica, a concentration (content) of the colloidal silica means the total amount thereof.

The polishing composition according to the present invention may further contain abrasive grains other than the colloidal silica within a range in which the effects of the present invention are not impaired. The other abrasive grains may be any of inorganic particles, organic particles, and organic-inorganic composite particles. Specific examples of the inorganic particles include particles formed of a metal oxide such as alumina, ceria, titania, or the like, silicon nitride particles, silicon carbide particles, boron nitride particles, and the like. Specific examples of the organic particles include polymethylmethacrylate (PMMA) particles. The other abrasive grains may be used alone or as a mixture of two or more kinds thereof. In addition, as the other abrasive grains, a commercially available product may be used, or a synthetic product may be used.

However, a concentration (content) of the other abrasive grains is preferably 5% by mass or less, more preferably 3% by mass or less, still more preferably 2% by mass or less, and particularly preferably 1% by mass or less, with respect to the total mass of the colloidal silica and the other abrasive grains. The most preferred mode is a mode in which the content of other abrasive grains is 0% by mass, that is, a mode in which abrasive grains other than colloidal silica are not contained.

### [Inorganic Salt Containing No Halogen]

The polishing composition according to the present invention contains an inorganic salt containing no halogen (hereinafter, also simply referred to as “inorganic salt”). It is considered that the defects on the surface of the polished object to be polished are reduced by the action of the anion contained in the inorganic salt as described above.

Examples of the inorganic salt containing no halogen include an inorganic salt composed of a cation and an anion shown below. Examples of the cation include an alkali metal ion such as a lithium ion, a sodium ion, a potassium ion, or the like, a group 2 metal (alkaline earth metal) ion such as a magnesium ion, a calcium ion, a strontium ion, or the like, a polyatomic ion such as an ammonium ion or the like, a complex ion, and the like. Examples of the anion include an oxoacid ion (a borate ion, a carbonate ion, a nitrate ion, a nitrite ion, a metasilicate ion, a phosphate ion, a monohydrogen phosphate ion, a dihydrogen phosphate ion, a phosphonate ion, a monohydrogen phosphonate ion, a phosphinate ion, a sulfate ion, a sulfonate ion, a sulfite ion, a thiosulfate ion, a chromate ion, a dichromate ion, a permanganate ion, or the like), a thiocyanate ion, a cyanate ion, a sulfamate ion, and the like.

More specific examples of an inorganic salt composed of an inorganic cation and an inorganic anion include lithium salts such as lithium carbonate, lithium nitrate, lithium thiocyanate, and the like; calcium salts such as calcium carbonate, calcium nitrate, calcium thiocyanate, and the like, and iron salts such as iron nitrate, iron thiocyanate, and the like; potassium salts such as potassium nitrate, potassium sulfate, potassium thiocyanate, potassium sulfamate, potassium phosphate, potassium dihydrogen phosphate, potassium monohydrogen phosphate, potassium monohydrogen phosphonate, and the like; sodium salts such as sodium nitrate, sodium sulfate, sodium thiocyanate, and the like; zinc salts such as zinc nitrate, zinc thiocyanate, and the like; magnesium salts such as magnesium nitrate, magnesium sulfate, magnesium thiocyanate, and the like; strontium salts such as strontium nitrate, strontium thiocyanate, and the like; ammonium nitrate, ammonium phosphate, ammonium dihydrogen phosphate, ammonium monohydrogen phosphate, ammonium phosphonate, ammonium monohydrogen phosphonate, ammonium sulfate, ammonium thiocyanate, ammonium sulfamate, and the like. These inorganic salts can be used alone or in combination of two or more kinds thereof. In addition, the inorganic salt may be a commercially available product or may be a synthetic product.

Among them, an inorganic salt in which a cation is a potassium ion or an ammonium ion and an anion is an oxoacid ion or a thiocyanate ion is preferable from the viewpoint of further exhibiting the effects of the present invention. Furthermore, the inorganic salt is more preferably at least one selected from the group consisting of ammonium sulfate, potassium sulfate, ammonium nitrate, potassium nitrate, ammonium thiocyanate, potassium thiocyanate, potassium sulfamate, ammonium phosphate, ammonium phosphonate, ammonium sulfamate, ammonium dihydrogen phosphate, ammonium monohydrogen phosphate, potassium phosphate, potassium dihydrogen phosphate, potassium monohydrogen phosphate, ammonium monohydrogen phosphonate, potassium phosphonate, and potassium monohydrogen phosphonate.

### <Parameter A>

In the polishing composition according to the present invention, the product (parameter A) of the valence number (unit: valency) of the anion of the inorganic salt and the concentration (unit: mM) of the anion of the inorganic salt in the polishing composition is 57 or more. In a case where the parameter A is less than 57, residues (preferably organic residues) on the surface of the polished object to be polished increase. The parameter A may be 59 or more, 60 or more, 63 or more, 65 or more, 68 or more, 70 or more, 75 or more, 80 or more, 85 or more, or 90 or more. An upper limit value of the parameter A is not particularly limited, is usually 300 or less, and may be 280 or less, 260 or less, 250 or less, 230 or less, 200 or less, 180 or less, or 150 or less.

### <<Method of Calculating Parameter A>>

In the present invention, the parameter A is calculated as follows.

The anion (conjugate base) contained in the inorganic salt is ionized in an aqueous solution to be in an equilibrium state (ionization equilibrium), and takes the form of a plurality of ion species.

### <Method of Calculating Abundance Ratio of Each Ion Species>

Sulfate ions will be described by way of example. The sulfate ions can take the form of non-ionized (zerovalent, H₂SO₄), monovalent ions (HSO₄⁻), and divalent ions (SO₄²⁻) in an aqueous solution. A zerovalent abundance ratio α0, a monovalent ion abundance ratio α1, and a divalent ion abundance ratio α2 can be determined from the pH of the aqueous solution and pKa1 and pKa2 of sulfuric acid. Specifically, α0, α1, and α2 are calculated from the following equations.

$$α 0 = {[ {H}^{+} ]}^{2} / ( {[ {H}^{+} ]}^{2} + Ka 1 [ {H}^{+} ] + Ka 1 Ka 2 ) \\ α 1 = ( Ka 1 \times [ {H}^{+} ] ) / ( {[ {H}^{+} ]}^{2} + Ka 1 [ {H}^{+} ] + Ka 1 Ka 2 ) \\ α 2 = ( Ka 1 \times Ka 2 ) / ( {[ {H}^{+} ]}^{2} + Ka 1 [ {H}^{+} ] + Ka 1 Ka 2 ) \\ Here , Ka 1 = {10}^{- pKa 1} , Ka 2 = {10}^{- pKa 2} , and [ {H}^{+} ] = {10}^{- pH} . \qquad [ Math . 1 ]$$

For example, in an aqueous solution with pH 2, since the abundance ratio of each ion species of sulfate ions is pKa1=−10 and pKa2=2.01 of the sulfate ions, it can be appreciated that

$$α 0 = {[ ( {10}^{( - 2 )} ]}^{2} / [ {( {10}^{- 2} )}^{2} + ( {10}^{10} ) \times ( {10}^{- 2} ) + ( {10}^{10} ) \times ( {10}^{- 2.01} ) ] = 0. ,$$

$$α 1 = [ ( {10}^{10} ) \times ( {10}^{- 2} ) ] / [ {( {10}^{- 2} )}^{2} +$$

$$( {10}^{10} ) \times ( {10}^{- 2} ) + ( {10}^{10} ) \times ( {10}^{- 2.01} ) ] = 0.506 ,$$

$$α 2 = [ ( {10}^{10} ) \times ( {10}^{- 2.01} ) ] / [ {( {10}^{- 2} )}^{2} + ( {10}^{10} ) \times$$

$$( {10}^{- 2} ) ) + ( {10}^{10} ) \times ( {10}^{- 2.01} ) ] = 0.494 ,$$

the abundance ratio α1 of the monovalent ion (HSO₄⁻) is 0.506, and the abundance ratio α2 of the divalent ion (SO₄²⁻) is 0.494.

In the present specification, the pH of the polishing composition is used as an actually calculated pH. In addition, as the pKa of the anion species in the inorganic salt, a value obtained from pKa calculation software, ACD/pKa, manufactured by ACD/Labs is adopted.

### <Valence Number of Anion>

In the present specification, the valence number T of the anion of the inorganic salt is not a formal valence number, but is represented by (formal valence number)×(abundance ratio of ion species of valence number thereof). In a polyvalent ion, the sum of (formal valence number)×(abundance ratio of ion species of valence number thereof) calculated for each ion species is adopted.

For example, in a case of a sulfate ion present in an aqueous solution with pH 2, it is calculated by the following equation:

$$T = 0 \times α 0 + 1 \times α 1 + 2 \times α 2$$

when each value calculated above is substituted,
T=0×0+1×0.506+2×0.494=1.49 (rounded off to the third decimal place) is derived.

The reason why not the formal valence number but the product of the formal valence number and the abundance ratio is adopted as the valence number of the anion of the inorganic salt is that the ratio of anion species generated from the inorganic salt varies depending on the pH of the polishing composition. In the present invention, it is considered that the anion of the inorganic salt is adsorbed to both the surface of polysilicon and the residues (particle residues, organic residues, and the like) that become defects on polysilicon. As a result, it is considered that both the surface and the residues of polysilicon are electrostatically negatively charged to generate electrostatic repulsive force, such that the residues are prevented from being attached to the surface of polysilicon and becoming defects. Therefore, it is important which valence number is present in a large number among the ion species of the anion. Therefore, the abundance ratio for each valence number of the anion is calculated and the product of the abundance ratio and the formal valence number is calculated, such that it is possible to more accurately express which anion species have a high ability to negatively charge polysilicon and residues at a designed pH.

Depending on the anionic species, trivalent ions may be generated. The abundance ratio α3 of the trivalent ions can be determined from the pH of the polishing composition and pka1, pKa2, and pKa3 of the anion species. Specifically, α3 is determined by the following equation.

$$α 3 = ( Ka 1 \times Ka 2 \times Ka 3 ) / ( {[ {H}^{+} ]}^{3} + Ka {1 [ {H}^{+} ]}^{2} + Ka 1 Ka 2 [ {H}^{+} ] + Ka 1 Ka 2 Ka 3 ) \qquad [ Math . 2 ]$$

Here, Ka1=10^{-pKa1}, Ka2=10^{-pKa2}, Ka3=10^{-pKa3}, and [H⁺]=10^{-pH}. The valence number T of the anion taking α3 into consideration is determined by T=0×α0+1×α1+2×α2+3×α3.

### <Valance Number of Anion×Concentration (Parameter A) of Anion in Polishing Composition>

It can be said that the valence number of the anion is an index indicating how much electrostatic force the anion species can impart to polysilicon or residues such as particle residues and organic residues under the pH condition of the polishing composition.

Furthermore, since the concentration of the anion is also related to the control of the surface potential of the polysilicon and the residues, it is possible to express how much electrostatic repulsive force can be imparted between the polysilicon and the residues as the entire polishing composition by calculating the product (parameter A) of the valence number of the anion and the concentration of the anion contained in the polishing composition.

For example, in a case where ammonium sulfate is contained at 100 mM under the condition of pH 2, when the parameter A is calculated,
(valence number T of sulfate ion at pH 2)×(concentration of anion contained in inorganic salt)=1.49×100 mM=149 [valency·mM] (rounded off to the nearest whole number). In the present invention, when the parameter A is 57 or more, an effect of reducing residues (preferably organic residues) on the polished object to be polished is obtained.

The concentration (content) of the inorganic salt in the polishing composition is not particularly limited as long as the parameter A is satisfied. In a case of a polishing composition used for polishing an object to be polished as a polishing solution as it is, a lower limit of the concentration (content) of the inorganic salt in the polishing composition is preferably 0.3% by mass or more, more preferably 0.4% by mass or more, still more preferably 0.45% by mass or more, and particularly preferably 0.5% by mass or more, with respect to the total mass of the polishing composition. In addition, an upper limit of the concentration (content) of the inorganic salt in the polishing composition is preferably 3.0% by mass or less, more preferably 2.5% by mass or less, still more preferably 2.0% by mass or less, and particularly preferably 1.5% by mass or less, with respect to the total mass of the polishing composition.

That is, the concentration (content) of the inorganic salt is preferably 0.3% by mass or more and 3.0% by mass or less, more preferably 0.4% by mass or more and 2.5% by mass or less, still more preferably 0.45% by mass or more and 2.0% by mass or less, and particularly preferably 0.5% by mass or more and 1.5% by mass or less, with respect to the total mass of the polishing composition.

Note that, in a case where the polishing composition contains two or more kinds of inorganic salts, a concentration (content) of the inorganic salts means the total amount thereof.

### [Water-Soluble Polymer]

The polishing composition according to the present invention contains a water-soluble polymer. The water-soluble polymer is not particularly limited, and any of a nonionic water-soluble polymer, an anionic water-soluble polymer, a cationic water-soluble polymer, and an amphoteric water-soluble polymer can be used. The water-soluble polymers can be used alone or in combination of two or more kinds thereof. In addition, the water-soluble polymer may be a commercially available product or may be a synthetic product.

In the present specification, the term “water-soluble” means that the solubility in water (25° C.) is 1 g/100 ml or more, and the term “polymer” refers to a (co)polymer having a weight average molecular weight (Mw) of 100 or more. Note that the weight average molecular weight (Mw) may be a catalog value, and can also be measured by gel permeation chromatography (GPC). In a case where the weight average molecular weight cannot be measured by GPC, the molecular weight calculated from the molecular formula can be adopted as the weight average molecular weight of the water-soluble polymer.

From the viewpoint of further improving the effects of the present invention, it is preferable that the water-soluble polymer according to the present invention includes a first water-soluble polymer which is adsorbed to the surface of polysilicon and has an action of changing the wettability of the surface from hydrophobic to hydrophilic. Such a first water-soluble polymer can prevent reattachment of residues to the surface of the polished object to be polished.

In addition, the water-soluble polymer according to the present invention preferably contains a second water-soluble polymer having an action of suppressing the polishing removal rate of polysilicon. Such a second water-soluble polymer can be adsorbed to the surface of polysilicon to form a protective film, and has an effect of inhibiting mechanical polishing action by colloidal silica.

### <First Water-Soluble Polymer>

The first water-soluble polymer that can be contained in the polishing composition according to the present invention is adsorbed to the surface of polysilicon, and has an effect of changing the wettability of the polysilicon surface from hydrophobic to hydrophilic. The water-soluble polymer used in the present invention is not particularly limited as long as it has the above effect, and a water-soluble polymer having at least one functional group selected from the group consisting of a nonionic group, an anionic group, and a cationic group in the molecule can be used. Examples of the water-soluble polymer include a water-soluble polymer having an alcoholic hydroxyl group, a carboxy group, an acyloxy group, a sulfo group, a quaternary ammonium structure, a heterocyclic structure, and a vinyl structure in the molecule. From the viewpoint of more easily obtaining the effect of the present application, the first water-soluble polymer is preferably a water-soluble polymer having an alcoholic hydroxyl group in a side chain.

The water-soluble polymer having an alcoholic hydroxyl group in a side chain is not particularly limited as long as it has such a structure, and a compound containing a vinyl alcohol unit (structural moiety represented by —CH₂—CH(OH)—; hereinafter, also referred to as “VA unit”) in the structure is preferable.

In the compound containing a VA unit in the structure, all repeating units may be substantially composed of the VA unit. In addition, the compound containing a VA unit in the structure may be a compound further containing a non-vinyl alcohol unit (a structural unit derived from a monomer other than vinyl alcohol, hereinafter, also referred to as “non-VA unit”) in addition to the VA unit. The non-VA unit is not particularly limited, and examples thereof include structural units derived from ethylene, vinyl acetate, vinyl propionate, vinyl hexanoate, 2-butenediol, and the like. In a case where a polymer containing a structural unit derived from vinyl alcohol contains a non-VA unit, the polymer may contain only one kind of non-VA unit, or may contain two or more kinds of non-VA units. In the compound containing a VA unit in the structure, a ratio of the number of moles of the VA unit to the number of moles of all repeating units is not particularly limited, and is preferably 50% or more, more preferably 65% or more, still more preferably 70% or more, and particularly preferably 75% or more (upper limit: 100%).

The water-soluble polymer having an alcoholic hydroxyl group in a side chain is preferably, for example, at least one selected from the group consisting of polyvinyl alcohol, a polyvinyl alcohol derivative (a polyvinyl alcohol derivative having an alcoholic hydroxyl group in a side chain), a copolymer of vinyl alcohol and another monomer (a copolymer of vinyl alcohol and another monomer, which has an alcoholic hydroxyl group in a side chain), and a derivative of the copolymer (a derivative of the copolymer of vinyl alcohol and another monomer, which has an alcoholic hydroxyl group in a side chain).

A saponification degree of polyvinyl alcohol is not particularly limited, and is preferably 50% by mole or more, more preferably 65% by mole or more, still more preferably 70% by mole or more, and particularly preferably 75% by moles or more (upper limit: 100% by mole).

Examples of the polyvinyl alcohol derivative include modified polyvinyl alcohol. The modified polyvinyl alcohol contains, as a non-VA unit, a structure in which a part of an alcoholic hydroxyl group of a vinyl alcohol unit is substituted with another functional group (hereinafter, also referred to as “modified VA unit”).

Examples of the modified polyvinyl alcohol include, but are not particularly limited to, carboxy-modified polyvinyl alcohol, sulfonic acid-modified polyvinyl alcohol, phosphoric acid-modified polyvinyl alcohol, silanol-modified polyvinyl alcohol, epoxy-modified polyvinyl alcohol, acetoacetyl-modified polyvinyl alcohol, nitrile-modified polyvinyl alcohol, pyrrolidone-modified polyvinyl alcohol, silicone-modified polyvinyl alcohol, amino-modified polyvinyl alcohol, quaternary amino-modified polyvinyl alcohol, and the like. In addition, examples of the modified polyvinyl alcohol include, but are not particularly limited to, a compound obtained by cyclic acetalization of polyvinyl alcohol (for example, polyvinyl butyral, polyvinyl propyral, polyvinyl ethyral, polyvinyl methylal, and the like) and the like.

The derivative of the copolymer of vinyl alcohol and another monomer is not particularly limited, and examples thereof include a compound further containing, in addition to the VA unit and the modified VA unit, a structural unit such as a structural unit derived from ethylene, a structural unit derived from vinyl ether having a long chain alkyl group, and a structural unit derived from a compound having at least one of an acryloyl group and a methacryloyl group, and the like.

As the water-soluble polymer having an alcoholic hydroxyl group in a side chain, polysaccharides are also preferably used. Examples of the polysaccharides include dextrin, maltodextrin, isomaltodextrin (branched maltodextrin), cyclodextrin, branched cyclodextrin, roasted dextrin, polymer dextrin, indigestible dextrin, inulin, inulin decomposition product, agave inulin, LM pectin, HM pectin, pullulan, guar gum, guar gum decomposition product, xanthan gum, gum arabic, ghatti gum, native gellan gum, deacylated gellan gum, locust bean gum, tara gum, galactomannan, glucomannan, konjac mannan, curdlan, carrageenan, karaya gum, cassia gum, tamarind seed gum, tragacanth gum, fenugreek gum, psyllium seed gum, succinoglycan, rhamsan gum, alginic acid, sodium alginate, alginate propylene glycol ester (PGA), soybean polysaccharide, methylcellulose, carboxymethylcellulose, hydroxypropylcellulose, hydroxypropylmethylcellulose, agar, fucoidan, porphyran, laminaran, starch, resistant starch, isomaltulose, polydextrose, indigestible glucan, arabinogalactan, and the like.

Among them, the first water-soluble polymer is more preferably at least one of polyvinyl alcohol and a butenediol-vinyl alcohol copolymer, and still more preferably a butenediol-vinyl alcohol copolymer.

A weight average molecular weight of the first water-soluble polymer is not particularly limited, and is preferably 1,000 or more, more preferably 3,000 or more, and still more preferably 5,000 or more. In addition, the weight average molecular weight of the first water-soluble polymer is not particularly limited, and is preferably 1,000,000 or less, more preferably 100,000 or less, and still more preferably 50,000 or less. That is, the weight average molecular weight of the first water-soluble polymer is preferably 1,000 or more and 1,000,000 or less, more preferably 3,000 or more and 100,000 or less, and still more preferably 5,000 or more and 50,000 or less.

The first water-soluble polymers may be used alone or in combination of two or more kinds thereof. In addition, as the first water-soluble polymer, a commercially available product may be used, or a synthetic product may be used.

From the viewpoint of further enhancing hydrophilicity of the object to be polished, a lower limit of a concentration (content) of the first water-soluble polymer in the polishing composition is preferably 0.005% by mass or more, more preferably 0.01% by mass or more, still more preferably 0.015% by mass or more, and particularly preferably 0.02% by mass or more, with respect to the total mass of the polishing composition. In addition, an upper limit of the concentration (content) of the first water-soluble polymer in the polishing composition is preferably 1% by mass or less, more preferably 0.8% by mass or less, still more preferably 0.5% by mass or less, and particularly preferably 0.3% by mass or less, with respect to the total mass of the polishing composition. That is, the concentration (content) of the first water-soluble polymer in the polishing composition is preferably 0.005% by mass or more and 1% by mass or less, more preferably 0.01% by mass or more and 0.8% by mass or less, still more preferably 0.015% by mass or more and 0.5% by mass or less, and particularly preferably 0.02% by mass or more and 0.3% by mass or less, with respect to the total mass of the polishing composition.

Note that, in a case where the polishing composition contains two or more kinds of first water-soluble polymers, a concentration (content) of the first water-soluble polymers means the total amount thereof.

### Second Water-Soluble Polymer

The second water-soluble polymer used in the present invention is not particularly limited as long as it has the above effect, and examples thereof include a nonionic compound and an anionic compound, and among them, a water-soluble polymer having a polyoxyalkylene chain is preferable. In addition, the second water-soluble polymer is more preferably a nonionic compound from the viewpoint of preventing electrostatic adsorption to other than polysilicon.

Note that the water-soluble polymer having an alcoholic hydroxyl group in a side chain and a polyoxyalkylene chain is classified as a second water-soluble polymer.

Examples of the second water-soluble polymer include polyethylene glycol (PEG), polypropylene glycol (PPG), polytetramethylene glycol, polytetramethylene ether glycol, polypentylene glycol, polyhexylene glycol, polyheptylene glycol, polyoctylene glycol, polynonylene glycol, polydecylene glycol, and polyoxyethylene nonylphenyl ether (POE nonylphenyl ether); at least two block copolymers or random copolymers selected from polyethylene glycol, polypropylene glycol, and polytetramethylene glycol; a random copolymer or a block copolymer of ethylene oxide and propylene oxide or ethylene oxide and butylene oxide; polyglycerin, and a polyethylene oxide-polyvinyl alcohol graft copolymer; and the like. Among them, the second water-soluble polymer is more preferably at least one of polypropylene glycol and polytetramethylene ether glycol.

A weight average molecular weight of the second water-soluble polymer is not particularly limited, and is preferably 100 or more, more preferably 200 or more, and still more preferably 300 or more. In addition, the weight average molecular weight of the second water-soluble polymer is not particularly limited, and is preferably 10,000 or less, more preferably 5,000 or less, and still more preferably 1,000 or less. That is, the weight average molecular weight of the second water-soluble polymer is preferably 100 or more and 10,000 or less, more preferably 200 or more and 5,000 or less, and still more preferably 300 or more and 1,000 or less.

The second water-soluble polymers may be used alone or in combination of two or more kinds thereof. In addition, as the second water-soluble polymer, a commercially available product may be used, or a synthetic product may be used.

A lower limit of the concentration (content) of the second water-soluble polymer in the polishing composition is preferably 0.05% by mass or more, more preferably 0.1% by mass or more, still more preferably 0.15% by mass or more, and particularly preferably 0.2% by mass or more, with respect to the total mass of the polishing composition. In addition, an upper limit of the concentration (content) of the second water-soluble polymer in the polishing composition is preferably 5% by mass or less, more preferably 3% by mass or less, still more preferably 1% by mass or less, and particularly preferably less than 1% by mass, with respect to the total mass of the polishing composition. That is, the concentration (content) of the second water-soluble polymer in the polishing composition is preferably 0.05% by mass or more and 5% by mass or less, more preferably 0.1% by mass or more and 3% by mass or less, still more preferably 0.15% by mass or more and 1% by mass or less, and particularly preferably 0.2% by mass or more and less than 1% by mass, with respect to the total mass of the polishing composition.

Note that, in a case where the polishing composition contains two or more kinds of second water-soluble polymers, a concentration (content) of the second water-soluble polymers means the total amount thereof.

### [pH and pH Adjusting Agent]

The pH of the polishing composition according to the present invention is not particularly limited, and is preferably 1.0 or more, more preferably 1.5 or more, and still more preferably 2.0 or more. In addition, the pH is preferably 7.0 or less, more preferably less than 5.0, still more preferably 4.5 or less, and particularly preferably 4.0 or less. That is, the pH of the polishing composition according to the present invention is preferably 1.0 or more and 7.0 or less, more preferably 1.0 or more and less than 5.0, still more preferably 1.5 or more and 4.5 or less, and particularly preferably 2.0 or more and 4.0 or less.

The polishing composition according to the present invention may contain a pH adjusting agent for adjusting pH. The pH adjusting agent may be either an acid or a base, or may be either an inorganic compound or an organic compound. The pH adjusting agents can be used alone or as a mixture of two or more kinds thereof.

Specific examples of acid that can be used as the pH adjusting agent include inorganic acids such as hydrochloric acid, sulfuric acid, nitric acid, hydrofluoric acid, boric acid, carbonic acid, hypophosphorous acid, phosphorous acid, phosphoric acid, and the like; and organic acids such as formic acid, acetic acid, propionic acid, butyric acid, pentanoic acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furan carboxylic acid, 2,5-furan dicarboxylic acid, 3-furan carboxylic acid, 2-tetrahydrofuran carboxylic acid, methoxy acetic acid, methoxy phenyl acetic acid, phenoxy acetic acid, and the like.

Examples of the base that can be used as the pH adjusting agent include amines such as aliphatic amine, aromatic amine, and the like, organic bases such as quaternary ammonium hydroxide and the like, hydroxides of alkali metals such as sodium hydroxide, potassium hydroxide, and the like, hydroxide of a group 2 element, ammonia, and the like.

The amount of pH adjusting agent added is not particularly limited, and may be adequately adjusted so that the polishing composition has a desired pH. In addition, the pH of the polishing composition can be measured by, for example, a pH meter, and specifically, can be measured by the method described in Examples.

### [Dispersing Medium]

The polishing composition according to the present invention preferably further contains a dispersing medium. As an example of the dispersing medium, water; alcohols such as methanol, ethanol, ethylene glycol, and the like; ketones such as acetone and the like, and a mixture thereof, and the like can be exemplified. Among them, water is preferable as the dispersing medium. That is, according to a more preferred embodiment of the present invention, the dispersing medium contains water. According to a still more preferred embodiment of the present invention, the dispersing medium is substantially formed of water. Note that the term “substantially” is intended to mean that a dispersing medium other than water can be contained as long as the effects of the object of the present invention can be achieved, and more specifically, the dispersing medium is preferably 90% by mass or more and 100% by mass or less of water and 0% by mass or more and 10% by mass or less of a dispersing medium other than water, and more preferably 99% by mass or more and 100% by mass or less of water and 0% by mass or more and 1% by mass or less of a dispersing medium other than water. Most preferably, the dispersing medium is water.

From the viewpoint of not inhibiting the action of the components contained in the polishing composition, as the dispersing medium, water containing as few impurities as possible is preferably, and specifically, pure water or ultrapure water, or distilled water obtained by removing foreign matter through a filter after removing impurity ions with an ion exchange resin is more preferable.

### [Electrical Conductivity of Polishing Composition]

An electrical conductivity (EC) of the polishing composition according to the present invention is not particularly limited, and is preferably 1 mS/cm or more and more preferably 3 mS/cm or more. In addition, the electrical conductivity (EC) of the polishing composition according to the present invention is preferably 20 mS/cm or less and more preferably 15 mS/cm or less. That is, the electrical conductivity (EC) of the polishing composition according to the present invention is preferably 1 mS/cm or more and 20 mS/cm or less and more preferably 3 mS/cm or more and 15 mS/cm or less. When the electrical conductivity (EC) of the polishing composition is in such a range, the polishing removal rate of silicon oxide and silicon nitride can be maintained high. In addition, repulsion between the colloidal silicas can be appropriately adjusted, and stability can be secured. The electrical conductivity of the polishing composition can be adjusted by the type and amount of the inorganic salt, the pH adjusting agent, and the like. The electrical conductivity (EC) of the polishing composition can be measured by the method described in Examples.

### [Other Components]

The polishing composition of the present invention may further contain other components such as a complexing agent, a metal anticorrosive, an antiseptic agent, an antifungal agent, an oxidizing agent, a reducing agent, a surfactant, and the like, as necessary. Hereinafter, the antiseptic agent and the antifungal agent that are preferred components will be described.

### (Antiseptic Agent and Antifungal Agent)

Examples of the antiseptic agent and the antifungal agent that can be added to the polishing composition according to the present invention include isothiazoline antiseptic agents such as 2-methyl-4-isothiazolin-3-one, 5-chloro-2-methyl-4-isothiazolin-3-one, and the like, paraoxybenzoic acid esters, phenoxyethanol, and the like. These antiseptic agents and antifungal agents may be used alone or as a mixture of two or more kinds thereof.

### [Form of Polishing Composition]

The polishing composition according to the present invention is typically supplied to an object to be polished in a form of a polishing solution containing a polishing composition, and is used for polishing the object to be polished. The polishing composition according to the present invention may be, for example, diluted (typically diluted with water) and used as a polishing solution, or may be used as it is as a polishing solution. That is, the concept of the polishing composition according to the present invention includes both a polishing composition (a working slurry) supplied to an object to be polished and used for polishing the object to be polished and a concentrated solution (an undiluted solution of a working slurry) diluted and used for polishing. A concentration rate of the concentrated solution can be, for example, about 2 times or more and 100 times or less in terms of volume, and usually about 3 times or more and 50 times or less is appropriate.

### [Object to be Polished]

The object to be polished according to the present invention is not particularly limited, and examples thereof include monocrystalline silicon, polycrystalline silicon (polysilicon), polycrystalline silicon doped with n-type or p-type impurities, amorphous silicon, amorphous silicon doped with n-type or p-type impurities, silicon oxide, silicon nitride, silicon carbonitride (SiCN), metal, SiGe, a carbon-containing material, and the like.

Examples of the object to be polished containing silicon oxide include a TEOS type silicon oxide film (hereinafter, also simply referred to as “TEOS” or “TEOS film”) produced by using tetraethyl orthosilicate as a precursor, a high density plasma (HDP) film, an undoped silicate glass (USG) film, a phosphorus silicate glass (PSG) film, a boron-phospho silicate glass (BPSG) film, a rapid thermal oxidation (RTO) film, and the like.

Examples of the metal include tungsten, copper, aluminum, cobalt, hafnium, nickel, gold, silver, platinum, palladium, rhodium, ruthenium, iridium, osmium, and the like.

Examples of the carbon-containing material include amorphous carbon, spin-on carbon (SOC), diamond-like carbon (DLC), nanocrystalline diamond, and graphene; SiOC (carbon-containing silicon oxide in which SiO₂ is doped with C) and silicon carbide, which are low dielectric constant (Low-k) materials; and the like. A film containing a carbon-containing material can be formed by a chemical vapor deposition (CVD) method, a physical vapor deposition (PVD) method, a spin coating method, or the like.

The object to be polished may be a commercially available product or may be produced by a known method.

Among them, an object to be polished containing at least one of silicon oxide and silicon nitride, and polysilicon is preferable. Therefore, according to a preferred embodiment of the present invention, the polishing composition is used for polishing an object to be polished containing at least one of silicon oxide and silicon nitride, and polysilicon.

### [Method of Producing Polishing Composition]

A method of producing a polishing composition according to the present embodiment is not particularly limited, and for example, the polishing composition can be obtained by stirring and mixing colloidal silica, an inorganic salt, a water-soluble polymer, and other additives added as necessary. Details of the respective components are as described above.

A temperature when the respective components are mixed is not particularly limited, and is preferably 10° C. or higher and 40° C. or lower, and heating may be performed to increase a rate of dissolution. In addition, a mixing time is also not particularly limited as long as uniform mixing can be achieved.

### [Polishing Method and Method of Manufacturing Semiconductor Substrate]

As described above, the polishing composition according to the present embodiment is particularly preferably used for polishing an object to be polished containing silicon oxide and silicon nitride. Therefore, the present invention provides a polishing method of polishing an object to be polished containing at least one of silicon oxide and silicon nitride, and polysilicon with the polishing composition according to the present embodiment. In addition, the present invention provides a method of manufacturing a semiconductor substrate containing at least one of silicon oxide and silicon nitride, and polysilicon, the method including polishing the semiconductor substrate by the polishing method.

As a polishing apparatus, it is possible to use a general polishing apparatus equipped with a holder for holding a substrate or the like including an object to be polished, a motor capable of changing a rotation speed, and the like, and having a polishing table to which a polishing pad (polishing cloth) can be attached.

As the polishing pad, a general nonwoven fabric, polyurethane, a porous fluororesin, or the like can be used without particular limitation. It is preferable that the polishing pad is subjected to groove processing so that a polishing solution is accumulated therein.

As for the polishing conditions, for example, the rotation speeds of the polishing table (platen) and the carrier (head) are preferably 10 rpm (0.17 s⁻¹) or more and 500 rpm (8.33 s⁻¹) or less. The pressure (polishing pressure) applied to the substrate including the object to be polished is preferably 0.5 psi (3.45 kPa) or more and 10 psi (68.9 kPa) or less.

A method of supplying the polishing composition to the polishing pad is also not particularly limited, and for example, a method of continuously supplying with a pump or the like is adopted. The supply amount is not particularly limited, and it is preferable that a surface of the polishing pad is always covered with the polishing composition according to the present invention.

The polishing composition according to the present embodiment may be a one-pack type or a multi-pack type including a two-pack type. In addition, the polishing composition according to the present invention may be prepared by diluting an undiluted solution of the polishing composition to, for example, 3 times or more using a diluent such as water or the like.

### [Selection Ratio]

As described above, the polishing composition according to the present invention has a high ratio (selection ratio) of a polishing removal rate of silicon oxide or silicon nitride to a polishing removal rate of polysilicon.

In the present invention, the ratio (silicon oxide/polysilicon) of the polishing removal rate of silicon oxide to the polishing removal rate of polysilicon is preferably 2 or more and more preferably 3 or more, and may be, for example, 4 or more, 5 or more, 6 or more, 7 or more, 8 or more, 9 or more, or 10 or more. In addition, the ratio (silicon nitride/polysilicon) of the polishing removal rate of silicon nitride to the polishing removal rate of polysilicon is preferably 2 or more and more preferably 3 or more, and may be, for example, 4 or more, 5 or more, 6 or more, 7 or more, 8 or more, 9 or more, or 10 or more.

### [Number of Residues]

As described above, the polishing composition according to the present invention can reduce the number of residues (preferably organic residues) on the surface of the polished object to be polished. The number of residues is preferably 100,000 or less, more preferably 80,000 or less, still more preferably 50,000 or less, still more preferably 10,000 or less, and particularly preferably 5,000 or less (lower limit: 0).

### [Scratch]

The polishing composition according to the present invention can reduce the number of scratches on the surface of the polished object to be polished. For example, the number of scratches on a polished object to be polished having a silicon oxide film is preferably 300 or less, more preferably 200 or less, still more preferably 100 or less, still more preferably 50 or less, and particularly preferably 30 or less (lower limit: 0). Note that the number of scratches can be measured by the method described in Examples.

Although embodiments of the present invention have been described in detail, they are illustrative and exemplary but not restrictive. It is clear that the scope of the present invention should be interpreted by the appended claims.

The present invention includes the following aspects and embodiments:
1. A polishing composition containing colloidal silica, an inorganic salt containing no halogen, and a water-soluble polymer, in which a product of a valence number (unit: valency) of an anion of the inorganic salt and a concentration (unit: mM) of the anion in the polishing composition is 57 or more;
2. The polishing composition according to 1. above, in which the colloidal silica is anion-modified colloidal silica;
3. The polishing composition according to 1. or 2. above, in which a pH is 1.0 or more and less than 5.0;
4. The polishing composition according to any one of 1. to 3. above, in which a product of a valence number (unit: valency) of an anion of the inorganic salt and a concentration (unit: mM) of the anion in the polishing composition is 300 or less;
5. The polishing composition according to any one of 1. to 4. above,
in which a cation of the inorganic salt is a potassium ion or an ammonium ion, and
the anion of the inorganic salt is an oxoacid ion or a thiocyanate ion;
6. The polishing composition according to any one of 1. to 5. above, in which the inorganic salt includes at least one selected from the group consisting of ammonium sulfate, potassium sulfate, ammonium nitrate, potassium nitrate, ammonium thiocyanate, potassium thiocyanate, potassium sulfamate, ammonium phosphate, ammonium phosphonate, ammonium sulfamate, ammonium dihydrogen phosphate, ammonium monohydrogen phosphate, potassium phosphate, potassium dihydrogen phosphate, potassium monohydrogen phosphate, ammonium monohydrogen phosphonate, potassium phosphonate, and potassium monohydrogen phosphonate;
7. The polishing composition according to any one of 1. to 6. above,
in which the water-soluble polymer includes a first water-soluble polymer and a second water-soluble polymer,
the first water-soluble polymer is a water-soluble polymer having an alcoholic hydroxyl group in a side chain, and
the second water-soluble polymer is a water-soluble polymer having a polyoxyalkylene chain;
8. The polishing composition according to 7. above,
in which the first water-soluble polymer is at least one of polyvinyl alcohol and a butenediol-vinyl alcohol copolymer, and
the second water-soluble polymer is at least one of polypropylene glycol and polytetramethylene ether glycol;
9. The polishing composition according to 7. or 8. above, in which the first water-soluble polymer is a butenediol-vinyl alcohol copolymer;
10. The polishing composition according to any one of 7. to 9. above, in which a concentration of the second water-soluble polymer in the polishing composition is 0.2% by mass or more and less than 1% by mass with respect to a total mass of the polishing composition;
11. The polishing composition according to any one of 1. to 10. above, further containing a dispersing medium;
12. The polishing composition according to any one of 1. to 11. above, in which the polishing composition is used for polishing of an object to be polished containing at least one of silicon oxide and silicon nitride, and polysilicon;
13. A polishing method including polishing an object to be polished containing at least one of silicon oxide and silicon nitride, and polysilicon using the polishing composition according to any one of 1. to 12. above; and
14. A method of manufacturing a semiconductor substrate, the method including polishing a semiconductor substrate containing at least one of silicon oxide and silicon nitride, and polysilicon by the polishing method according to 13. above.

### EXAMPLES

The present invention will be described in more detail with reference to the following Examples and Comparative Examples. However, the technical scope of the present invention is not limited to only the following Examples. Unless otherwise specified, “%” and “part(s)” refer to “% by mass” and “part(s) by mass”, respectively. In addition, in the following Examples, unless otherwise specified, operations were performed under a condition of room temperature (20° C. or higher and 25° C. or lower)/relative humidity of 40% RH or more and 50% RH or less. Note that each physical property was measured as follows.

### <Average Secondary Particle Size of Abrasive Grains>

An average secondary particle size of abrasive grains was measured as a volume average particle size (arithmetic mean diameter based on volume: Mv) by a dynamic light scattering particle size/particle size distribution apparatus UPA-UTI151 (manufactured by Nikkiso Co., Ltd.).

### <pH of Polishing Composition>

A pH of the polishing composition was measured by a pH meter (model number: LAQUA, manufactured by Horiba, Ltd.).

### <Weight Average Molecular Weight of Water-Soluble Polymer>

A weight average molecular weight of the water-soluble polymer was measured under the following measurement conditions using gel permeation chromatography (GPC).

### (GPC Measurement Conditions)

Measuring apparatus: HLC-8320GPC (manufactured by Tosoh Corporation)
Sample concentration: 0.01% by mass
Column: TSKgel GMPWXL
Detector: differential refractometer
Eluent: solution obtained by dissolving 10 mM lithium bromide in N,N-dimethylformamide
Flow rate: 1 mL/min
Measurement temperature: 40° C.
Molecular weight conversion: polyethylene glycol conversion
Sample injection amount: 200 μL

### <Electrical Conductivity of Polishing Composition>

The electrical conductivity (EC) of the polishing composition was measured by a desktop electrical conductivity meter (model: DS-71 LAQUA (registered trademark), manufactured by Horiba, Ltd.).

### <Sulfonic Acid-Immobilized Colloidal Silica>

The sulfonic acid-immobilized colloidal silica contained in the polishing composition was prepared by the method described in “Sulfonic acid-functionalized silica through quantitative oxidation of thiol groups”, Chem. Commun. 246-247 (2003) using colloidal silica having an average primary particle size of 35 nm, an average secondary particle size of 70 nm, and an average degree of association of 2.

### Example 1

### <Preparation of Polishing Composition>

Sulfonic acid-immobilized colloidal silica (average secondary particle size: 70 nm, cocoon-shaped) was added to water as a dispersing medium so that a final concentration was 3% by mass. Furthermore, polyvinyl alcohol (PVA, weight average molecular weight (Mw): 10,000, manufactured by Japan Vam & Poval Co., Ltd., product name: JMR-10HH) was added so that a final concentration was 0.075% by mass, polypropylene glycol (PPG, weight average molecular weight (Mw): 400, manufactured by Sanyo Chemical Industries, Ltd.) was added so that a final concentration was 0.6% by mass, and ammonium sulfate (manufactured by TOMIYAMA PURE CHEMICAL INDUSTRIES, LTD.) as an inorganic salt was added so that a final concentration was 35.50 mM (0.47% by mass), and stirring and mixing were performed (stirring temperature: 25° C., stirring time: 20 minutes). A pH of the polishing composition was adjusted to pH 2.50 using sulfuric acid to complete a polishing composition 1.

### Example 2

A polishing composition 2 was prepared in the same manner as that of Example 1, except that ammonium sulfate was added so that a final concentration in the composition was 47.00 mM (0.62% by mass).

### Example 3

A polishing composition 3 was prepared in the same manner as that of Example 2, except that instead of sulfuric acid, nitric acid was added so that a pH of the composition was 2.10.

### Examples 4 and 5

Polishing compositions 4 and 5 were prepared in the same manner as that of Example 3, except that ammonium nitrate (manufactured by FUJIFILM Wako Pure Chemical Corporation) was used instead of ammonium sulfate and was added so that a final concentration was the molar concentration shown in Table 1, and nitric acid was further added so that a pH of the composition was 2.50.

### Example 6

A polishing composition 6 was prepared in the same manner as that of Example 4, except that potassium sulfate (manufactured by FUJIFILM Wako Pure Chemical Corporation) was used instead of ammonium nitrate and was added so that a final concentration in the composition was 35.50 mM (0.62% by mass).

### Example 7

A polishing composition 7 was prepared in the same manner as that of Example 4, except that potassium nitrate (manufactured by FUJIFILM Wako Pure Chemical Corporation) was used instead of ammonium nitrate and was added so that a final concentration in the composition was 71.00 mM (0.72% by mass).

### Example 8

A polishing composition 8 was prepared in the same manner as that of Example 4, except that ammonium thiocyanate (manufactured by FUJIFILM Wako Pure Chemical Corporation) was used instead of ammonium nitrate and was added so that a final concentration in the composition was 71.00 mM (0.54% by mass).

### Example 9

A polishing composition 9 was prepared in the same manner as that of Example 4, except that potassium thiocyanate (manufactured by FUJIFILM Wako Pure Chemical Corporation) was used instead of ammonium nitrate and was added so that a final concentration in the composition was 71.00 mM (0.69% by mass).

### Example 10

A polishing composition 10 was prepared in the same manner as that of Example 4, except that ammonium sulfamate (ammonium amidosulfate, manufactured by Tokyo Chemical Industry Co., Ltd.) was used instead of ammonium nitrate and was added so that a final concentration in the composition was 71.00 mM (0.81% by mass).

### Examples 11 and 12

Polishing compositions 11 and 12 were prepared in the same manner as that of Example 4, except that phosphoric acid (manufactured by RASA Industries, LTD.) and ammonia (KANTO CHEMICAL CO., INC.) were used instead of ammonium nitrate and each were added so that a final concentration of ammonium dihydrogen phosphate in the composition was the molar concentration shown in Table 1.

### Examples 13 and 14

Polishing compositions 13 and 14 were prepared in the same manner as that of Example 4, except that phosphonic acid (manufactured by KANTO CHEMICAL CO., INC.) and ammonia (manufactured by KANTO CHEMICAL CO., INC.) were used instead of ammonium sulfate and each were added so that a final concentration of ammonium monohydrogen phosphonate in the composition was the molar concentration shown in Table 1.

### Example 15

Sulfonic acid-immobilized colloidal silica (average secondary particle size: 70 nm, cocoon-shaped) was added to water as a dispersing medium so that a final concentration was 2.3% by mass. Furthermore, a butenediol-vinyl alcohol copolymer (BVOH, degree of polymerization: 300, manufactured by Mitsubishi Chemical Corporation, product name: Nichigo G-Polymer AZF8035W) was added so that a final concentration was 0.075% by mass, polypropylene glycol (weight average molecular weight: 400, manufactured by Sanyo Chemical Industries, Ltd.) was added so that a final concentration was 0.6% by mass, and ammonium sulfate (manufactured by TOMIYAMA PURE CHEMICAL INDUSTRIES, LTD.) as an inorganic salt was added so that a final concentration was 38.14 mM (0.50% by mass), and stirring and mixing were performed (stirring temperature: 25° C., stirring time: 20 minutes). A pH of the polishing composition was adjusted to pH 2.10 using nitric acid to prepare a polishing composition 15.

### Example 16

Sulfonic acid-immobilized colloidal silica (average secondary particle size: 70 nm, cocoon-shaped) was added to water as a dispersing medium so that a final concentration was 2.3% by mass. Furthermore, polyvinyl alcohol (PVA, weight average molecular weight (Mw): 10,000, manufactured by Japan Vam & Poval Co., Ltd., product name: JMR-10HH) was added so that a final concentration was 0.075% by mass, polypropylene glycol (PPG, weight average molecular weight (Mw): 400, manufactured by Sanyo Chemical Industries, Ltd.) was added so that a final concentration was 0.6% by mass, and ammonium sulfate (manufactured by TOMIYAMA PURE CHEMICAL INDUSTRIES, LTD.) as an inorganic salt was added so that a final concentration was 38.14 mM (0.50% by mass), and stirring and mixing were performed (stirring temperature: 25° C., stirring time: 20 minutes). A pH of the polishing composition was adjusted to pH 2.10 using nitric acid to complete a polishing composition 16.

### Example 17

A polishing composition 17 was prepared in the same manner as that of Example 16, except that polypropylene glycol (weight average molecular weight: 400, manufactured by Sanyo Chemical Industries, Ltd.) was added so that a final concentration was 0.05% by mass.

### Example 18

A polishing composition 18 was prepared in the same manner as that of Example 16, except that polypropylene glycol (weight average molecular weight: 400, manufactured by Sanyo Chemical Industries, Ltd.) was added so that a final concentration was 0.1% by mass.

### Example 19

A polishing composition 19 was prepared in the same manner as that of Example 16, except that polypropylene glycol (weight average molecular weight: 400, manufactured by Sanyo Chemical Industries, Ltd.) was added so that a final concentration was 0.15% by mass.

### Example 20

A polishing composition 20 was prepared in the same manner as that of Example 16, except that polypropylene glycol (weight average molecular weight: 400, manufactured by Sanyo Chemical Industries, Ltd.) was added so that a final concentration was 0.2% by mass.

### Example 21

A polishing composition 21 was prepared in the same manner as that of Example 16, except that polypropylene glycol (weight average molecular weight: 400, manufactured by Sanyo Chemical Industries, Ltd.) was added so that a final concentration was 0.4% by mass.

### Comparative Example 1

A polishing composition of Comparison 1 was prepared in the same manner as that of Example 1, except that no inorganic salt was added.

### Comparative Example 2

A polishing composition of Comparison 2 was prepared in the same manner as that of Example 1, except that ammonium sulfate was added so that a final concentration in the composition was 23.50 mM (0.31% by mass).

### Comparative Example 3

A polishing composition of Comparison 3 was prepared in the same manner as that of Example 4, except that no inorganic salt was added.

### Comparative Example 4

A polishing composition of Comparison 4 was prepared in the same manner as that of Example 4, except that ammonium nitrate was added so that a final concentration in the composition was 47.00 mM (0.38% by mass).

### Comparative Example 5

A polishing composition of Comparison 5 was prepared in the same manner as that of Example 4, except that citric acid (manufactured by FUSO CHEMICAL CO., LTD.) and ammonia (KANTO CHEMICAL CO., INC.) were used instead of ammonium nitrate and each were added so that a final concentration of ammonium citrate in the composition was 71.00 mM (0.49% by mass).

### Comparative Example 6

A polishing composition of Comparison 6 was prepared in the same manner as that of Example 4, except that phosphoric acid (manufactured by RASA Industries, LTD.) and ammonia (KANTO CHEMICAL CO., INC.) were used instead of ammonium nitrate and each were added so that a final concentration of ammonium dihydrogen phosphate in the composition was 71.00 mM (0.82% by mass).

### Comparative Example 7

A polishing composition of Comparison 7 was prepared in the same manner as that of Example 4, except that hydrochloric acid (manufactured by KANTO CHEMICAL CO., INC.) and ammonia (KANTO CHEMICAL CO., INC.) were used instead of ammonium sulfate and each were added so that a final concentration of ammonium chloride in the composition was 71.00 mM (0.37% by mass).

### Comparative Example 8

A polishing composition of Comparison 8 was prepared in the same manner as that of Example 4, except that (−)-10-camphorsulfonic acid (manufactured by Tokyo Chemical Industry Co., Ltd.) and ammonia (KANTO CHEMICAL CO., INC.) were used instead of ammonium sulfate and each were added so that a final concentration of ammonium 10-camphorsulfonate in the composition was 71.00 mM (1.77% by mass).

The configurations of the polishing compositions of Examples and Comparative Examples are shown in Tables 1 and 2. Note that, in Table 2, “-” means that the component is not contained.

TABLE 1

| | | Abrasive | | | | First water-soluble | | | Second water-soluble | | | | | |
|---|---|---|---|---|---|---|---|---|---|---|---|---|---|---|
| | | grain | | | | polymer | | | polymer | | | pH adjusting | | |
| | | Concen- | Inorganic salt | | | | | Concen- | | | Concen- | agent | | |
| | Compo- | tration | | Concentration | | | | tration | | | tration | | Compo- | Electrical |
| | sition | % by | | | (% by | | | (% by | | | (% by | | sition | conductivity |
| | No. | mass | Type | (mM) | mass) | Type | Mw | mass) | Type | Mw | mass) | Type | pH | (mS/cm) |
| Example | 1 | 3 | Ammonium | 35.50 | 0.47 | PVA | 10000 | 0.075 | PPG | 400 | 0.6 | Sulfuric | 2.50 | 9.26 |
| 1 | | | sulfate | | | | | | | | | acid | | |
| Example | 2 | 3 | Ammonium | 47.00 | 0.62 | PVA | 10000 | 0.075 | PPG | 400 | 0.6 | Sulfuric | 2.50 | 11.49 |
| 2 | | | sulfate | | | | | | | | | acid | | |
| Example | 3 | 3 | Ammonium | 47.00 | 0.62 | PVA | 10000 | 0.075 | PPG | 400 | 0.6 | Nitric | 2.10 | 13.29 |
| 3 | | | sulfate | | | | | | | | | acid | | |
| Example | 4 | 3 | Ammonium | 71.00 | 0.57 | PVA | 10000 | 0.075 | PPG | 400 | 0.6 | Nitric | 2.50 | 10.18 |
| 4 | | | nitrate | | | | | | | | | acid | | |
| Example | 5 | 3 | Ammonium | 94.00 | 0.75 | PVA | 10000 | 0.075 | PPG | 400 | 0.6 | Nitric | 2.50 | 12.78 |
| 5 | | | nitrate | | | | | | | | | acid | | |
| Example | 6 | 3 | Potassium | 35.50 | 0.62 | PVA | 10000 | 0.075 | PPG | 400 | 0.6 | Nitric | 2.50 | 9.52 |
| 6 | | | sulfate | | | | | | | | | acid | | |
| Example | 7 | 3 | Potassium | 71.00 | 0.72 | PVA | 10000 | 0.075 | PPG | 400 | 0.6 | Nitric | 2.50 | 10.06 |
| 7 | | | nitrate | | | | | | | | | acid | | |
| Example | 8 | 3 | Ammonium | 71.00 | 0.54 | PVA | 10000 | 0.075 | PPG | 400 | 0.6 | Nitric | 2.50 | 9.92 |
| 8 | | | thiocyanate | | | | | | | | | acid | | |
| Example | 9 | 3 | Potassium | 71.00 | 0.69 | PVA | 10000 | 0.075 | PPG | 400 | 0.6 | Nitric | 2.50 | 9.93 |
| 9 | | | thiocyanate | | | | | | | | | acid | | |
| Example | 10 | 3 | Ammonium | 71.00 | 0.81 | PVA | 10000 | 0.075 | PPG | 400 | 0.6 | Nitric | 2.50 | 9.93 |
| 10 | | | sulfamate | | | | | | | | | acid | | |
| Example | 11 | 3 | Ammonium | 94.00 | 1.08 | PVA | 10000 | 0.075 | PPG | 400 | 0.6 | Nitric | 2.50 | 7.63 |
| 11 | | | dihydrogen | | | | | | | | | acid | | |
| | | | phosphate | | | | | | | | | | | |
| Example | 12 | 3 | Ammonium | 128.00 | 1.47 | PVA | 10000 | 0.075 | PPG | 400 | 0.6 | Nitric | 2.50 | 9.54 |
| 12 | | | dihydrogen | | | | | | | | | acid | | |
| | | | phosphate | | | | | | | | | | | |
| Example | 13 | 3 | Ammonium | 71.00 | 0.70 | PVA | 10000 | 0.075 | PPG | 400 | 0.6 | Nitric | 2.50 | 6.77 |
| 13 | | | monohydrogen | | | | | | | | | acid | | |
| | | | phosphonate | | | | | | | | | | | |
| Example | 14 | 3 | Ammonium | 94.00 | 0.93 | PVA | 10000 | 0.075 | PPG | 400 | 0.6 | Nitric | 2.50 | 8.91 |
| 14 | | | monohydrogen | | | | | | | | | acid | | |
| | | | phosphonate | | | | | | | | | | | |
| Example | 15 | 2.3 | Ammonium | 38.14 | 0.50 | BVOH | 10000 | 0.075 | PPG | 400 | 0.6 | Nitric | 2.10 | 12.02 |
| 15 | | | sulfate | | | | | | | | | acid | | |
| Example | 15 | 2.3 | Ammonium | 38.14 | 0.50 | PVA | 10000 | 0.075 | PPG | 400 | 0.6 | Nitric | 2.50 | 12.00 |
| 16 | | | sulfate | | | | | | | | | acid | | |
| Example | 15 | 2.3 | Ammonium | 38.14 | 0.50 | PVA | 10000 | 0.075 | PPG | 400 | 0.05 | Nitric | 2.50 | 12.02 |
| 17 | | | sulfate | | | | | | | | | acid | | |
| Example | 15 | 2.3 | Ammonium | 38.14 | 0.50 | PVA | 10000 | 0.075 | PPG | 400 | 0.1 | Nitric | 2.50 | 12.01 |
| 18 | | | sulfate | | | | | | | | | acid | | |
| Example | 15 | 2.3 | Ammonium | 38.14 | 0.50 | PVA | 10000 | 0.075 | PPG | 400 | 0.15 | Nitric | 2.50 | 12.05 |
| 19 | | | sulfate | | | | | | | | | acid | | |
| Example | 15 | 2.3 | Ammonium | 38.14 | 0.50 | PVA | 10000 | 0.075 | PPG | 400 | 0.2 | Nitric | 2.50 | 12.07 |
| 20 | | | sulfate | | | | | | | | | acid | | |
| Example | 15 | 2.3 | Ammonium | 38.14 | 0.50 | PVA | 10000 | 0.075 | PPG | 400 | 0.4 | Nitric | 2.50 | 12.04 |
| 21 | | | sulfate | | | | | | | | | acid | | |

TABLE 2

| | | Abrasive | | | | First water- | | | Second water- | | | | | |
|---|---|---|---|---|---|---|---|---|---|---|---|---|---|---|
| | | grain | | | | soluble polymer | | | soluble polymer | | | pH adjusting | | |
| | | Concen- | Inorganic salt | | | | | Concen- | | | Concen- | agent | | |
| | Compo- | tration | | Concentration | | | | tration | | | tration | | Compo- | Electrical |
| | sition | % by | | | (% by | | | (% by | | | (% by | | sition | conductivity |
| | No. | mass | Type | (mM) | mass) | Type | Mw | mass) | Type | Mw | mass) | Type | pH | (mS/cm) |
| Comparative | Compar- | 3 | — | — | — | PVA | 10000 | 0.075 | PPG | 400 | 0.6 | Sulfuric | 2.50 | 1.80 |
| Example 1 | ison | | | | | | | | | | | acid | | |
| | 1 | | | | | | | | | | | | | |
| Comparative | Compar- | 3 | Ammonium | 23.50 | 0.31 | PVA | 10000 | 0.075 | PPG | 400 | 0.6 | Sulfuric | 2.50 | 6.91 |
| Example 2 | ison | | sulfate | | | | | | | | | acid | | |
| | 2 | | | | | | | | | | | | | |
| Comparative | Compar- | 3 | — | — | — | PVA | 10000 | 0.075 | PPG | 400 | 0.6 | Nitric | 2.50 | 1.67 |
| Example 3 | ison | | | | | | | | | | | acid | | |
| | 3 | | | | | | | | | | | | | |
| Comparative | Compar- | 3 | Ammonium | 47.00 | 0.38 | PVA | 10000 | 0.075 | PPG | 400 | 0.6 | Nitric | 2.50 | 7.49 |
| Example 4 | ison | | nitrate | | | | | | | | | acid | | |
| | 4 | | | | | | | | | | | | | |
| Comparative | Compar- | 3 | Ammonium | 71.00 | 0.49 | PVA | 10000 | 0.075 | PPG | 400 | 0.6 | Nitric | 2.50 | 9.92 |
| Example 5 | ison | | citrate | | | | | | | | | acid | | |
| | 5 | | | | | | | | | | | | | |
| Comparative | Compar- | 3 | Ammonium | 71.00 | 0.82 | PVA | 10000 | 0.075 | PPG | 400 | 0.6 | Nitric | 2.50 | 5.30 |
| Example 6 | ison | | dihydrogen | | | | | | | | | acid | | |
| | 6 | | phosphate | | | | | | | | | | | |
| Comparative | Compar- | 3 | Ammonium | 71.00 | 0.37 | PVA | 10000 | 0.075 | PPG | 400 | 0.6 | Nitric | 2.50 | 9.92 |
| Example 7 | ison | | chloride | | | | | | | | | acid | | |
| | 7 | | | | | | | | | | | | | |
| Comparative | Compar- | 3 | Ammonium | 71.00 | 1.77 | PVA | 10000 | 0.075 | PPG | 400 | 0.6 | Nitric | 2.50 | 9.93 |
| Example 8 | ison | | 10- | | | | | | | | | acid | | |
| | 8 | | camphor- | | | | | | | | | | | |
| | | | sulfonate | | | | | | | | | | | |

### <Calculation of Parameter A>

The parameter A of each Example and each Comparative Example was calculated as follows.

As the pKa of the anion species in the inorganic salt, a value obtained from pKa calculation software, ACD/pKa, manufactured by ACD/Labs was used.

### <Method of Calculating Abundance Ratio of Each Ion Species>

Abundance ratios α0 (an abundance ratio of non-ionized ion species), α1 (an abundance ratio of monovalent ions), α2 (the abundance ratio of divalent ions), and α3 (an abundance ratio of trivalent ions) of each ion species of the anion were calculated by the following equation.

$$α 0 = {[ {H}^{+} ]}^{2} / ( {[ {H}^{+} ]}^{2} + Ka 1 [ {H}^{+} ] + Ka 1 Ka 2 ) \\ α 1 = ( Ka 1 \times [ {H}^{+} ] ) / ( {[ {H}^{+} ]}^{2} + Ka 1 [ {H}^{+} ] + Ka 1 Ka 2 ) \\ α 2 = ( Ka 1 \times Ka 2 ) / ( {[ {H}^{+} ]}^{2} + Ka 1 [ {H}^{+} ] + Ka 1 Ka 2 ) \\ α 3 = ( Ka 1 \times Ka 2 \times Ka 3 ) / ( {[ {H}^{+} ]}^{3} + Ka {1 [ {H}^{+} ]}^{2} + Ka 1 Ka 2 [ {H}^{+} ] + Ka 1 Ka 2 Ka 3 ) \\ Here , Ka 1 = {10}^{- pKa 1} , Ka 2 = {10}^{- pKa 2} , Ka 3 = {10}^{- pKa 3} , \\ and [ {H}^{+} ] = {10}^{- pH} . \qquad [ Math . 3 ]$$

As for a valence number T of the ion species of the inorganic salt, the sum of (formal valence number)×(abundance ratio of ion species of valence number thereof) calculated for each ion species was calculated and adopted:

$$T = 0 \times α 0 + 1 \times α 1 + 2 \times α 2 + 3 \times α 3$$

a product of the calculated T (unit: valency) and the concentration (unit: mM) of the anion of the inorganic salt was calculated, and the calculated product was used as a value of a parameter A.

The values that are calculation bases of the parameter A and the values of the parameter A in each of Examples and each of Comparative Examples are shown in Tables 3 and 4.

TABLE 3

| | | | Inorganic salt | | Anion of inorganic salt | | | | | | | |
|---|---|---|---|---|---|---|---|---|---|---|---|---|
| | Compo- | Compo- | | Concen- | | | | | | | Valence | Param- |
| | sition | sition | | tration | | | | | | | number | eter |
| | No. | pH | Type | (mM) | pKa1 | pka2 | pKa3 | α1 | α2 | α3 | T | A |
| Example 1 | 1 | 2.50 | Ammonium | 35.50 | −10 | 2.01 | — | 0.24448 | 0.75552 | — | 1.76 | 62 |
| | | | sulfate | | | | | | | | | |
| Example 2 | 2 | 2.50 | Ammonium | 47.00 | −10 | 2.01 | — | 0.24448 | 0.75552 | — | 1.76 | 83 |
| | | | sulfate | | | | | | | | | |
| Example 3 | 3 | 2.10 | Ammonium | 47.00 | −10 | 2.01 | — | 0.44838 | 0.55162 | — | 1.55 | 73 |
| | | | sulfate | | | | | | | | | |
| Example 4 | 4 | 2.50 | Ammonium | 71.00 | −1.4 | — | — | 1 | — | — | 1.00 | 71 |
| | | | nitrate | | | | | | | | | |
| Example 5 | 5 | 2.50 | Ammonium | 94.00 | −1.4 | — | — | 1 | — | — | 1.00 | 94 |
| | | | nitrate | | | | | | | | | |
| Example 6 | 6 | 2.50 | Potassium | 35.50 | −10 | 2.01 | — | 0.24448 | 0.75552 | — | 1.76 | 62 |
| | | | sulfate | | | | | | | | | |
| Example 7 | 7 | 2.50 | Potassium | 71.00 | −1.4 | — | — | 1 | — | — | 1.00 | 71 |
| | | | nitrate | | | | | | | | | |
| Example 8 | 8 | 2.50 | Ammonium | 71.00 | 0.93 | — | — | 0.97 | — | — | 0.97 | 69 |
| | | | thiocyanate | | | | | | | | | |
| Example 9 | 9 | 2.50 | Potassium | 71.00 | 0.93 | — | — | 0.97 | — | — | 0.97 | 69 |
| | | | thiocyanate | | | | | | | | | |
| Example 10 | 10 | 2.50 | Ammonium | 71.00 | 0.93 | — | — | 0.97 | — | — | 0.97 | 69 |
| | | | sulfamate | | | | | | | | | |
| Example 11 | 11 | 2.50 | Ammonium | 94.00 | 1.97 | 7.21 | 12.32 | 0.72212 | 1.50551 × | 2.27868 × | 0.77 | 73 |
| | | | dihydrogen | | | | | | 10⁻⁵ | 10⁻¹⁵ | | |
| | | | phosphate | | | | | | | | | |
| Example 12 | 12 | 2.50 | Ammonium | 128.00 | 1.97 | 7.21 | 12.32 | 0.72212 | 1.50551 × | 2.27868 × | 0.77 | 99 |
| | | | dihydrogen | | | | | | 10⁻⁵ | 10⁻¹⁵ | | |
| | | | phosphate | | | | | | | | | |
| Example 13 | 13 | 2.50 | Ammonium | 71.00 | 1.24 | 6.79 | — | 0.94786 | 4.86122 × | — | 0.95 | 67 |
| | | | mono- | | | | | | 10⁻⁵ | | | |
| | | | hydrogen | | | | | | | | | |
| | | | phosphonate | | | | | | | | | |
| Example 14 | 14 | 2.50 | Ammonium | 94.00 | 1.24 | 6.79 | — | 0.94786 | 4.86122 × | — | 0.95 | 89 |
| | | | mono- | | | | | | 10⁻⁵ | | | |
| | | | hydrogen | | | | | | | | | |
| | | | phosphonate | | | | | | | | | |
| Example 15 | 15 | 2.10 | Ammonium | 38.14 | −10 | 2.01 | — | 0.44838 | 0.55162 | — | 1.55 | 59 |
| | | | sulfate | | | | | | | | | |
| Example 16 | 16 | 2.10 | Ammonium | 38.14 | −10 | 2.01 | — | 0.44838 | 0.55162 | — | 1.55 | 59 |
| | | | sulfate | | | | | | | | | |
| Example 17 | 17 | 2.10 | Ammonium | 38.14 | −10 | 2.01 | — | 0.44838 | 0.55162 | — | 1.55 | 59 |
| | | | sulfate | | | | | | | | | |
| Example 18 | 18 | 2.10 | Ammonium | 38.14 | −10 | 2.01 | — | 0.44838 | 0.55162 | — | 1.55 | 59 |
| | | | sulfate | | | | | | | | | |
| Example 19 | 19 | 2.10 | Ammonium | 38.14 | −10 | 2.01 | — | 0.44838 | 0.55162 | — | 1.55 | 59 |
| | | | sulfate | | | | | | | | | |
| Example 20 | 20 | 2.10 | Ammonium | 38.14 | −10 | 2.01 | — | 0.44838 | 0.55162 | — | 1.55 | 59 |
| | | | sulfate | | | | | | | | | |
| Example 21 | 21 | 2.10 | Ammonium | 38.14 | −10 | 2.01 | — | 0.44838 | 0.55162 | — | 1.55 | 59 |
| | | | sulfate | | | | | | | | | |

TABLE 4

| | | | | Anion of inorganic salt | | | | | | | | |
|---|---|---|---|---|---|---|---|---|---|---|---|---|
| | Compo- | Compo- | Inorganic | Concen- | | | | | | | Valence | Param- |
| | sition | sition | salt | tration | | | | | | | number | eter |
| | No. | pH | Type | (mM) | pKa1 | pKa2 | pKa3 | α1 | α2 | α3 | T | A |
| Comparative | Compar- | 2.50 | — | — | — | — | — | — | — | — | — | 0 |
| Example 1 | ison | | | | | | | | | | | |
| | 1 | | | | | | | | | | | |
| Comparative | Compar- | 2.50 | Ammonium | 23.50 | −10 | 2.01 | — | 0.24448 | 0.75552 | — | 1.76 | 41 |
| Example 2 | ison | | sulfate | | | | | | | | | |
| | 2 | | | | | | | | | | | |
| Comparative | Compar- | 2.50 | — | — | — | — | — | — | — | — | — | 0 |
| Example 3 | ison | | | | | | | | | | | |
| | 3 | | | | | | | | | | | |
| Comparative | Compar- | 2.50 | Ammonium | 47.00 | −1.4 | — | — | 1 | — | — | 1.00 | 47 |
| Example 4 | ison | | nitrate | | | | | | | | | |
| | 4 | | | | | | | | | | | |
| Comparative | Compar- | 2.50 | Ammonium | 71.00 | 3.09 | 4.75 | 6.41 | 0.20425 | 0.00115 | 1.41303 × 10⁻⁷ | 0.21 | 15 |
| Example 5 | ison | | citrate | | | | | | | | | |
| | 5 | | | | | | | | | | | |
| Comparative | Compar- | 2.50 | Ammonium | 71.00 | 1.97 | 7.21 | 12.32 | 0.72212 | 1.50551 × 10⁻⁵ | 2.27868 × 10⁻¹⁵ | 0.77 | 55 |
| Example 6 | ison | | dihydrogen | | | | | | | | | |
| | 6 | | phosphate | | | | | | | | | |
| Comparative | Compar- | 2.50 | Ammonium | 71.00 | −8 | — | — | 1 | — | — | 1.00 | 71 |
| Example 7 | ison | | chloride | | | | | | | | | |
| | 7 | | | | | | | | | | | |
| Comparative | Compar- | 2.50 | Ammonium | 71.00 | 1.17 | — | — | 0.95532 | — | — | 0.96 | 68 |
| Example 8 | ison | | 10- | | | | | | | | | |
| | 8 | | camphor- | | | | | | | | | |
| | | | sulfonate | | | | | | | | | |

### [Evaluation]

As for the object to be polished, an object to be polished in which a polysilicon film having a thickness of 1,000 Å, a silicon oxide film having a thickness of 1,000 Å, or a silicon nitride film having a thickness of 1,000 Å was formed on a surface of a silicon wafer (300 mm, blanket wafer) was used as each of objects to be polished (in Table 2, the objects to be polished are represented as Poly-Si, SiO₂, and Si₃N₄, respectively). Note that the silicon oxide film is derived from tetraethyl orthosilicate (TEOS). Each object to be polished was polished under the following conditions.

### <Polishing Conditions>

Polishing machine: 300 mm polishing machine (model number: F-REX300E, manufactured by Ebara Corporation)
Polishing pad: polyurethane pad (IC1000, manufactured by NITTA DuPont Incorporated)
Pressure: 2.0 psi (13.79 kPa)
Polishing table (platen) rotation speed: 30 rpm
Carrier (head) rotation speed: 31 rpm
Flow rate of polishing composition: 200 ml/min
Polishing time: 60 seconds

### <Polishing Removal Rate and Selection Ratio>

The polishing removal rate (polishing rate) of the object to be polished was calculated by the following equation.

$$Polishing removal rate [ Å / min ] = \qquad [ Math . 4 ]$$

$$( thickness [ Å ] before polishing - thickness [ Å ] after polishing ) /$$

$$polishing time [ min ]$$

The thicknesses of the object to be polished before and after polishing were determined by a light interference type film thickness measurement apparatus (model number: A-SET F5X, manufactured by KLA-Tencor Corporation), and the polishing removal rate was calculated by dividing the difference by the polishing time. In addition, the ratio (SiO₂/poly-si) of the polishing removal rate of the silicon oxide film to the polishing removal rate of the polysilicon film and the ratio (Si₃N₄/poly-si) of the polishing removal rate of the silicon nitride film to the polishing removal rate of the polysilicon film, that is, the selection ratios were calculated.

### <Number of Residues>

The total number of residues (defects) having a size of 0.07 μm or more remaining on the surface of the polished object to be polished having a polysilicon film was measured using Surfscan (registered trademark) SP-5 manufactured by KLA-Tencor Corporation.

### <Scratch>

The total number of defects having a size of 0.05 μm or more generated on the surface of the polished object to be polished having a silicon oxide film was measured using Surfscan (registered trademark) SP-5 manufactured by KLA-Tencor Corporation. Thereafter, SEM images of all defects were observed using Hitachi Multipass SEM (Scanning Electron Microscope) RS6000 Inspago manufactured by Hitachi High-Technologies Corporation, and the number of concave defects was counted as scratches.

The evaluation results of the polishing removal rate, the selection ratio, the number of residues, and the scratches are shown in Table 5.

TABLE 5

| | | | | | Polishing removal | | Number | |
|---|---|---|---|---|---|---|---|---|
| | | Polishing removal rate | | | rate selection ratio | | of | |
| | Parameter | poly-Si | SiO₂ | Si₃N₄ | SiO₂/ | Si₃N₄/ | residues | Scratches |
| | A | (Å/min) | (Å/min) | (Å/min) | poly-Si | poly-Si | (number) | (number) |
| Example 1 | 62 | 26 | 215 | 211 | 8.27 | 8,12 | 11779 | 22 |
| Example 2 | 83 | 30 | 238 | 196 | 7.93 | 6.53 | 493 | 24 |
| Example 3 | 73 | 29 | 243 | 213 | 8.38 | 7.34 | 768 | 21 |
| Example 4 | 71 | 20 | 230 | 208 | 11.5 | 10.4 | 53314 | 23 |
| Example 5 | 94 | 25 | 240 | 210 | 9.6 | 8.4 | 529 | 20 |
| Example 6 | 62 | 27 | 215 | 211 | 7.96 | 7.81 | 43979 | 23 |
| Example 7 | 71 | 21 | 229 | 200 | 10.9 | 9.5 | 57540 | 26 |
| Example 8 | 69 | 22 | 209 | 212 | 9.5 | 9.6 | 60480 | 21 |
| Example 9 | 69 | 18 | 207 | 216 | 11.5 | 12.0 | 90417 | 24 |
| Example 10 | 69 | 23 | 200 | 218 | 8.7 | 9.5 | 6069 | 20 |
| Example 11 | 73 | 29 | 198 | 230 | 6.8 | 7.9 | 84148 | 19 |
| Example 12 | 99 | 29 | 201 | 213 | 6.9 | 7.3 | 365 | 20 |
| Example 13 | 67 | 22 | 190 | 211 | 8.6 | 9.6 | 24227 | 22 |
| Example 14 | 89 | 29 | 199 | 222 | 6.9 | 7.7 | 5435 | 24 |
| Example 15 | 59 | 28 | 187 | 21 | 6.68 | 7.54 | 1063 | 13 |
| Example 16 | 59 | 30 | 213 | 213 | 7.10 | 7.10 | 2103 | 69 |
| Example 17 | 59 | 93 | 213 | 205 | 2.29 | 2.21 | 1301 | 235 |
| Example 18 | 59 | 78 | 214 | 210 | 2.74 | 2.69 | 1373 | 193 |
| Example 19 | 59 | 61 | 211 | 208 | 3.46 | 3.41 | 1249 | 143 |
| Example 20 | 59 | 50 | 214 | 205 | 4.28 | 4.10 | 1559 | 98 |
| Example 21 | 59 | 39 | 212 | 209 | 5.44 | 5.37 | 1137 | 39 |
| Comparative | 0 | 19 | 147 | 256 | 7.74 | 13.47 | 354854 | 40 |
| Example 1 | | | | | | | | |
| Comparative | 41 | 23 | 192 | 226 | 8.35 | 9.82 | 102641 | 22 |
| Example 2 | | | | | | | | |
| Comparative | 0 | 16 | 147 | 256 | 9.19 | 16.0 | 368172 | 43 |
| Example 3 | | | | | | | | |
| Comparative | 47 | 26 | 166 | 239 | 6.40 | 9.2 | 311433 | 21 |
| Example 4 | | | | | | | | |
| Comparative | 15 | 16 | 186 | 237 | 11.6 | 14.8 | 370382 | 29 |
| Example 5 | | | | | | | | |
| Comparative | 55 | 21 | 147 | 240 | 7.0 | 11.4 | 354886 | 30 |
| Example 6 | | | | | | | | |
| Comparative | 71 | 19 | 186 | 213 | 9.8 | 11.2 | 413778 | 39 |
| Example 7 | | | | | | | | |
| Comparative | 68 | 26 | 183 | 222 | 7.0 | 8.5 | 435421 | 31 |
| Example 8 | | | | | | | | |

As is apparent from Table 5, it was found that in the case where the polishing composition of each of Examples was used, the ratio of the polishing removal rate of the silicon oxide film to the polishing removal rate of the polysilicon film and the ratio (selection ratio) of the polishing removal rate of the silicon nitride film to the polishing removal rate of the polysilicon film were high, and the residues and scratches on the surface of the polished object to be polished were reduced. On the other hand, it was found that in the case where the polishing composition of each of Comparative Examples was used, the residues on the surface of the polished objected to be polished increased.

In addition, comparing Examples 16 to 21, there was a tendency for the number of scratches to decrease as the concentration of polypropylene glycol increased.

Note that Table 5 shows the results obtained by separately polishing an object to be polished having a polysilicon film, an object to be polished having a silicon oxide film, and an object to be polished having a silicon nitride film. However, even in a case where the object to be polished having both at least one of the silicon oxide film and the silicon nitride film and the polysilicon film is polished, it is presumed that the same polishing removal rate, selection ratio, number of residues, and scratch results as those in Table 5 can be obtained.

The present application is based on the Japanese patent application No. 2023-010766 filed on Jan. 27, 2023, and the Japanese patent application No. 2023-199620 filed on Nov. 27, 2023, and a disclosed content thereof is incorporated herein as a whole by reference.

What is claimed is:

1. A polishing composition comprising: colloidal silica, inorganic salt containing no halogen, and water-soluble polymer,
wherein a product of a valence number (unit: valency) of anion of the inorganic salt and a concentration (unit: mM) of the anion in the polishing composition is 57 or more.

2. The polishing composition according to claim 1, wherein the colloidal silica is anion-modified colloidal silica.

3. The polishing composition according to claim 1, wherein a pH is 1.0 or more and less than 5.0.

4. The polishing composition according to claim 1, wherein a product of a valence number (unit: valency) of anion of the inorganic salt and a concentration (unit: mM) of the anion in the polishing composition is 300 or less.

5. The polishing composition according to claim 1,
wherein a cation of the inorganic salt is a potassium ion or an ammonium ion, and
the anion of the inorganic salt is an oxoacid ion or a thiocyanate ion.

6. The polishing composition according to claim 1, wherein the inorganic salt includes at least one selected from the group consisting of ammonium sulfate, potassium sulfate, ammonium nitrate, potassium nitrate, ammonium thiocyanate, potassium thiocyanate, potassium sulfamate, ammonium phosphate, ammonium phosphonate, ammonium sulfamate, ammonium dihydrogen phosphate, ammonium monohydrogen phosphate, potassium phosphate, potassium dihydrogen phosphate, potassium monohydrogen phosphate, ammonium monohydrogen phosphonate, potassium phosphonate, and potassium monohydrogen phosphonate.

7. The polishing composition according to claim 1,
wherein the water-soluble polymer includes a first water-soluble polymer and a second water-soluble polymer,
the first water-soluble polymer is a water-soluble polymer having an alcoholic hydroxyl group in a side chain, and
the second water-soluble polymer is a water-soluble polymer having a polyoxyalkylene chain.

8. The polishing composition according to claim 7,
wherein the first water-soluble polymer is at least one of polyvinyl alcohol and butenediol-vinyl alcohol copolymer, and
the second water-soluble polymer is at least one of polypropylene glycol and polytetramethylene ether glycol.

9. The polishing composition according to claim 7, wherein the first water-soluble polymer is butenediol-vinyl alcohol copolymer.

10. The polishing composition according to claim 7, wherein a concentration of the second water-soluble polymer in the polishing composition is 0.2% by mass or more and less than 1% by mass with respect to a total mass of the polishing composition.

11. The polishing composition according to claim 1, further comprising a dispersing medium.

12. The polishing composition according to claim 1, wherein the polishing composition is used for polishing of an object to be polished containing at least one of silicon oxide and silicon nitride, and polysilicon.

13. A polishing method comprising polishing an object to be polished containing at least one of silicon oxide and silicon nitride, and polysilicon using the polishing composition according to claim 1.

14. A method of manufacturing a semiconductor substrate, the method comprising polishing a semiconductor substrate containing at least one of silicon oxide and silicon nitride, and polysilicon by the polishing method according to claim 13.
